(19) United States
(12) Patent Application Publication
(10) Pub. No.: US 2023/0215697 A1
(43) Pub. Date: Jul. 6, 2023

(54) REMOTE PLASMA UNIT AND SUBSTRATE PROCESSING APPARATUS INCLUDING REMOTE PLASMA

(71) Applicant: ASM IP Holding B.V., Almere (NL)

(72) Inventor: Ping Ren, Tokyo (JP)

(21) Appl. No.: 18/092,362

(22) Filed: Jan. 2, 2023

Related U.S. Application Data
(60) Provisional application No. 63/296,628, filed on Jan. 5, 2022.

(51) Int. Cl. H01J 37/32

(52) U.S. Cl. CPC H01J 37/32357; H01J 37/32899; H01J 37/32862; H01J 37/32449; H01J 2237/332

(57) ABSTRACT

A substrate processing apparatus is disclosed. Exemplary substrate processing apparatus includes a plurality of reaction chambers; a shared remote plasma unit; a plurality of first cleaning gas lines configured to fluidly couple the shared remote plasma unit to the reaction chambers; and a cleaning gas source to provide the shared remote plasma unit with a cleaning gas; wherein each of the first cleaning gas lines is provided with a valve and is connected to a sidewall of the reaction chamber.

### CROSS-REFERENCE TO RELATED APPLICATIONS

This application claims priority to U.S. Provisional Patent Application Ser. No. 63/296,628 filed Jan. 5, 2022 titled REMOTE PLASMA UNIT AND SUBSTRATE PROCESSING APPARATUS INCLUDING REMOTE PLASMA, the disclosure of which is hereby incorporated by reference in its entirety.

### FIELD OF INVENTION

The present disclosure relates generally to a remote plasma unit. More particularly, exemplary embodiments of the present disclosure relate to a remote plasma unit and a substrate processing apparatus including a remote plasma unit.

### BACKGROUND OF THE DISCLOSURE

In order to increase throughput of processed wafers, multiple wafers are loaded in a reaction chamber and processed simultaneously, by executing batch programs. However, it is difficult to perform processing with high precision using batch programs. On the other hand, if a single wafer is loaded in a reaction chamber and processed, the process can be controlled with high precision, but throughput suffers. If multiple reaction chambers of the single-wafer processing type share a common process and cleaning gas supply system and a remote plasma system (RPU), simultaneous operation of the multiple reaction chambers may increase throughput. An exemplary substrate processing apparatus is disclosed in U.S. Pat. No. 9,447,498, which is hereby incorporated by reference.

However, when the multiple reaction chambers share a cleaning gas line, during deposition, cross talk through the cleaning line may occur, thereby causing variations among the reaction chambers in terms of film uniformity, film composition, etc.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a plurality of reaction chambers; a shared remote plasma unit; a plurality of first cleaning gas lines configured to fluidly couple the shared remote plasma unit to the reaction chambers; and a cleaning gas source to provide the shared remote plasma unit with a cleaning gas; wherein each of the first cleaning gas lines is provided with a valve and is connected to a sidewall of the reaction chamber.

In various embodiments, the cleaning gas may comprise at least one of Ar, O2, NF3, C2F6, or SF6.

In various embodiments, the substrate processing apparatus may further comprise a susceptor positioned within the reaction chamber to be constructed and arranged to support a substrate.

In various embodiments, the substrate processing apparatus may further comprise a shower plate to be constructed and arranged to face the susceptor.

In various embodiments, the shower plate may be provided with a plurality of holes to supply the cleaning gas.

In various embodiments, the substrate processing apparatus may further comprise a plurality of second cleaning lines, each of which is disposed between the shared remote plasma unit and the shower plate.

In various embodiments, each of the second cleaning gas line may be provided with a process gas line to supply a process gas to the reaction chamber through the shower plate.

In various embodiments, each valve may be configured to be closed while the process gas is being supplied to the reaction chamber.

In various embodiments, a substrate processing apparatus may comprise a plurality of reaction chambers; a shared remote plasma unit; a plurality of first cleaning gas lines configured to fluidly couple the shared remote plasma unit to the reaction chambers; and a cleaning gas source to provide the shared remote plasma unit with a cleaning gas; wherein the first cleaning gas lines share a valve and each of the first cleaning gas lines is connected to a sidewall of the reaction chamber.

In various embodiments, the substrate processing apparatus may further comprise a susceptor positioned within the reaction chamber to be constructed and arranged to support a substrate.

In various embodiments, the substrate processing apparatus may further comprise a shower plate to be constructed and arranged to face the susceptor.

In various embodiments, the substrate processing apparatus may further comprise a plurality of second cleaning lines, each of which is disposed between the shared remote plasma unit and the shower plate.

In various embodiments, each of the second cleaning gas line may be provided with a process gas line to supply a process gas to the reaction chamber through the shower plate.

In various embodiments, the valve may be configured to be closed while the process gas is being supplied to the reaction chamber.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with dual chamber modules usable in an embodiment of the present invention.

FIG. 2 is a schematic cross-sectional view of a dual chamber module in an embodiment of the present invention.

FIG. 3 is a schematic cross-sectional view of a dual chamber module in another embodiment of the present invention.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied.

As used herein, the term “substrate” may refer to any underlying material or materials that may be used, or upon which, a device, a circuit, or a film may be formed, which is typically semiconductor wafer.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

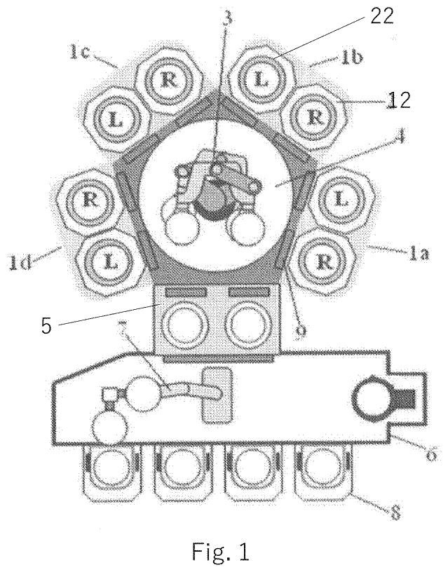

FIG. 1 is a schematic plan view of a substrate processing apparatus with dual chamber modules in an embodiment of the present invention. The substrate processing apparatus may comprise four process modules 1a, 1b, 1c, 1d (each provided with two reaction chambers 12, 22), a load lock chamber 5, and a substrate handling chamber 4 provided with back end robots 3.

In this embodiment, the substrate processing apparatus may comprise: (i) four process modules 1a-1d, each having two reaction chambers 12, 22 arranged side by side with their fronts aligned in a line; (ii) a substrate handling chamber 4 including two back end robots 3 (substrate handling robots); and (iii) a load lock chamber 5 for loading or unloading two substrates simultaneously, the load lock chamber 5 being attached to the one additional side of the substrate handling chamber 4, wherein each back end robot 3 is accessible to the load lock chamber 5. Each of the back end robots 3 have at least two end-effectors accessible to the two reaction chambers of each unit simultaneously, said substrate handling chamber 4 having a polygonal shape having four sides corresponding to and being attached to the four process modules 1a-1d, respectively, and one additional side for a load lock chamber 5, all the sides being disposed on the same plane. The interior of each reaction chamber 12, 22 and the interior of the load lock chamber 5 may be isolated from the interior of the substrate handling chamber 4 by a gate valve 9.

In some embodiments, a controller (not shown) may store software programmed to execute sequences of substrate transfer, for example. The controller may also: check the status of each process chamber; position substrates in each process chamber using sensing systems, controls, a gas box, and an electric box for each module; control a front end robot 7 in an equipment front end module 6 based on a distribution status of substrates stored in FOUP 8 and a load lock chamber 5; control back end robots 3; and control gate valves 9 and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 1, the apparatus has eight reaction chambers, but it may have ten or more. In some embodiments, the reactors of the modules may be any suitable reactors for processing or treating wafers, including CVD reactors (such as plasma-enhanced CVD reactors and thermal CVD reactors) or ALD reactors (such as plasma-enhanced ALD reactors and thermal ALD reactors). Typically, the reaction chambers may be plasma reactors for depositing a thin film or layer on a wafer. In some embodiments, all the modules may be of the same type having identical capabilities for treating wafers so that the unloading/loading can sequentially and regularly be timed, thereby increasing productivity or throughput. In some embodiments, the modules may have different capabilities (e.g., different treatments) but their handling times may be substantially identical.

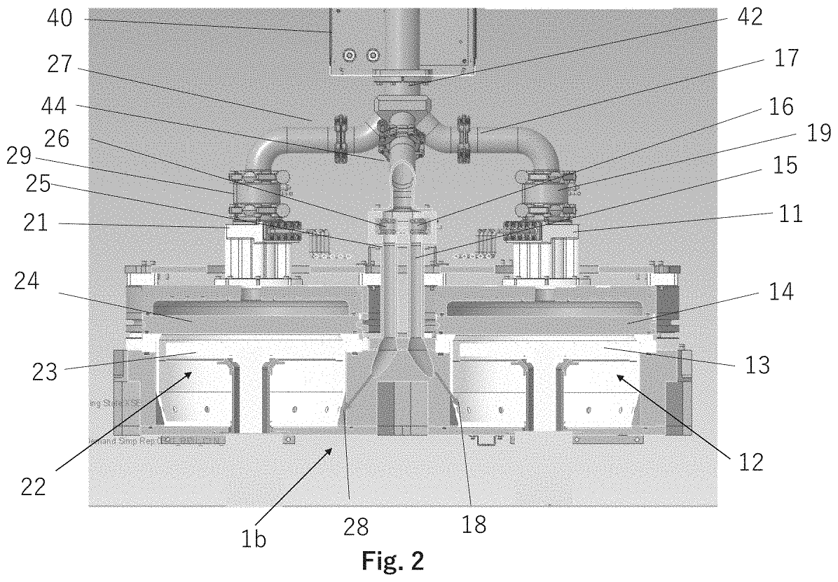

FIG. 2 is a schematic cross-sectional view of a dual chamber module in an embodiment of the present invention. In the reaction chamber 12, a shower plate 14 and a susceptor 13 may be provided, and in the reaction chamber 22, a shower plate 24 and a susceptor 23 may be provided. The susceptors 13, 23 may support a substrate and be heated by an incorporated heater or an external heater, thereby controlling a temperature of the substrate.

The shower plates 14, 24 may be constructed and arranged to face the susceptors 13, 23. The shower plates 14, 24 may be provided with a plurality of holes such a process gas is supplied to the substrate placed on the susceptor 13, 23, thereby causing the deposition of a thin film onto the substrate.

A remote plasma unit (RPU) 40 may be disposed above the reaction chambers 12, 22. A cleaning gas may be supplied to the RPU 40 from a cleaning gas source (not shown), thereby turning into gas radicals, gas ions, or both (reactive gases). The cleaning gas may be at least one of, for example, Ar, O₂, NF₃, C₂F₆, or SF₆.

The cleaning gases may be introduced into the reaction chambers 12, 22 using a central gas line 42 and second cleaning gas lines 17, 27 through the showerheads 14, 24. The second cleaning gas lines 17, 27 may be arranged substantially symmetrically between the reaction chambers 12, 22 from the splitting point. A first end of the central gas line 42 may be connected to the RPU 40. The other end of the central gas line 42 may be split into three gas lines, which are the second cleaning gas lines 17, 27 and the third cleaning gas line 44.

Each of the second cleaning gas lines 17, 27 may be provided with RPU gate valves 19, 29 and process gas lines 11, 21. The RPU gate valves 19, 29 may be closed when a process gas is being supplied to substrates through the process gas lines 11, 21 and the showerhead 14, 24, thereby preventing the cleaning gas from being mixed into the process gas.

The cleaning gas may be also introduced into lower regions of the reaction chambers 12, 22 using the central gas line 42, the third cleaning gas line 44, and first cleaning gas lines 15, 25 through holes 18, 28 disposed sidewalls of the reaction chambers 12, 22. The first cleaning gas lines 15, 25 may be arranged substantially symmetrically between the reaction chambers 12, 22 from the splitting point to the reaction chambers 12, 22. Each first cleaning gas line 15, 25 may be provided with valves 16, 26.

A controller (not shown) may be configured to control the valves 16, 26 between an open position and a closed position. The valves 16, 26 may be closed when the process gas is being supplied to substrates, thereby preventing a cross talk between the reaction chambers 12, 22.

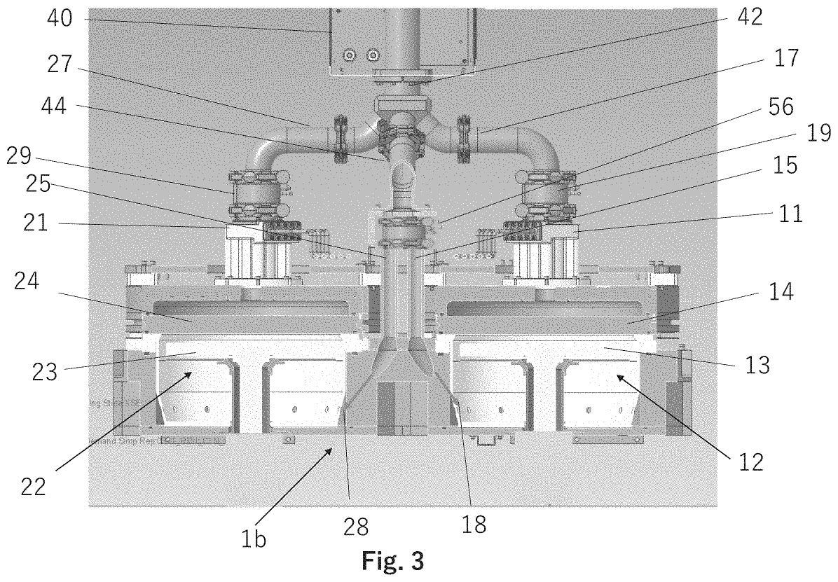

FIG. 3 is a schematic cross-sectional view of a dual chamber module in another embodiment of the present invention. Instead of the valves 16, 26 in FIG. 2, the first cleaning gas lines 15, 25 may share a valve 56 to close both lines 15, 25 simultaneously. The valves 56 may be also closed when the process gas is being supplied to substrates, thereby preventing a cross talk between the reaction chambers 12, 22.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a plurality of reaction chambers;
a shared remote plasma unit;
a plurality of first cleaning gas lines configured to fluidly couple the shared remote plasma unit to the reaction chambers; and
a cleaning gas source to provide the shared remote plasma unit with a cleaning gas;
wherein each of the first cleaning gas lines is provided with a valve and is connected to a sidewall of the reaction chamber.

2. The substrate processing apparatus according to claim 1, wherein the cleaning gas comprises at least one of Ar, O₂, NF₃, C₂F₆, or SF₆.

3. The substrate processing apparatus according to claim 1, further comprising a susceptor positioned within the reaction chamber to be constructed and arranged to support a substrate.

4. The substrate processing apparatus according to claim 3, further comprising a shower plate to be constructed and arranged to face the susceptor.

5. The substrate processing apparatus according to claim 4, wherein the shower plate is provided with a plurality of holes to supply the cleaning gas.

6. The substrate processing apparatus according to claim 5, further comprising a plurality of second cleaning lines, each of which is disposed between the shared remote plasma unit and the shower plate.

7. The substrate processing apparatus according to claim 6, wherein each of the second cleaning gas line is provided with a process gas line to supply a process gas to the reaction chamber through the shower plate.

8. The substrate processing apparatus according to claim 7, wherein each valve is configured to be closed while the process gas is being supplied to the reaction chamber.

9. A substrate processing apparatus, comprising:
a plurality of reaction chambers;
a shared remote plasma unit;
a plurality of first cleaning gas lines configured to fluidly couple the shared remote plasma unit to the reaction chambers; and
a cleaning gas source to provide the shared remote plasma unit with a cleaning gas;
wherein the first cleaning gas lines share a valve and each of the first cleaning gas lines is connected to a sidewall of the reaction chamber.

10. The substrate processing apparatus according to claim 9, further comprising a susceptor positioned within the reaction chamber to be constructed and arranged to support a substrate.

11. The substrate processing apparatus according to claim 10, further comprising a shower plate to be constructed and arranged to face the susceptor.

12. The substrate processing apparatus according to claim 11, further comprising a plurality of second cleaning lines, each of which is disposed between the shared remote plasma unit and the shower plate.

13. The substrate processing apparatus according to claim 12, wherein each of the second cleaning gas line is provided with a process gas line to supply a process gas to the reaction chamber through the shower plate.

14. The substrate processing apparatus according to claim 13, wherein the valve is configured to be closed while the process gas is being supplied to the reaction chamber.
